(19) United States
(12) Patent Application Publication
(10) Pub. No.: US 2020/0243736 A1
(43) Pub. Date: Jul. 30, 2020

(54) SEMICONDUCTOR DEVICE AND FABRICATION METHOD FOR THE SAME

(71) Applicant: Enkris Semiconductor, Inc., Suzhou City (CN)

(72) Inventor: Liyang Zhang, Suzhou City (CN)

(21) Appl. No.: 15/764,822

(22) PCT Filed: Jan. 12, 2017
(86) PCT No.: PCT/CN2017/070987

§ 371 Date: Mar. 29, 2018

(51) Int. Cl. H01L 33/62; H01L 33/46; H01L 33/38; H01L 33/50; H01L 33/00

(52) U.S. Cl. CPC H01L 33/62; H01L 33/46; H01L 33/382; H01L 33/505; H01L 2933/0041; H01L 33/0093; H01L 2933/0016; H01L 2933/0025; H01L 2933/0066; H01L 33/502

(57) ABSTRACT

Provided are a semiconductor device and a fabrication method for the same. The semiconductor device includes a substrate, a bonding metal layer, a reflective layer, a first conductive layer, an active layer, a second conductive layer, a first electrode and a second electrode. The first electrode runs from one side of the substrate that is away from the bonding metal layer, successively through the substrate, the bonding metal layer, the reflective layer, the second conductive layer and the active layer, and extends to the first conductive layer, with the first electrode connected with the first conductive layer. The second electrode is provided on one side of the substrate away from the bonding metal layer. The semiconductor device has a structure where the second conductive layer is shared, which provides more homogeneous light emission and higher light extraction efficiency, eliminates the interference among pixel units.

### TECHNICAL FIELD

The present disclosure relates to the field of semiconductor device, and particularly to a semiconductor device and a fabrication method for the same.

### BACKGROUND ART

Micro-LED display technique is implemented by an all solid state light-emitting device integrated with a high-density two-dimensional light emitting diode array are on a chip. Compared with other micro-display technologies, a LED micro-display system has a simple design which may reduce the overall volume and weight of the system, and has a low manufacturing cost, and meanwhile provides advantages such as low power consumption, high use efficiency of light energy, quick response speed, wide range of working temperature and high anti-interference capability. However, the inventor found that the LED micro-display chips in the prior art have poor consistency in the wavelength of the emitted light and low light extraction efficiency.

### SUMMARY OF THE DISCLOSURE

In view of this, an object of the present disclosure is to provide a semiconductor device and a fabrication method for the same. To this end, the embodiments of the present disclosure employ the following technical solutions.

A semiconductor device includes a substrate, a bonding metal layer, a reflective layer, a first conductive layer, an active layer, a second conductive layer, at least one first electrode and at least one second electrode.
Specifically, the bonding metal layer is provided on one side of the substrate;
the reflective layer is provided on one side of the bonding metal layer that is away from the substrate;
the second conductive layer is provided on one side of the reflective layer that is away from the bonding metal layer;
the active layer is provided on one side of the second conductive layer that is away from the reflective layer;
the first conductive layer is provided on one side of the active layer that is away from the second conductive layer;
the at least one first electrode runs, from one side of the substrate that is away from the bonding metal layer, successively through the substrate, the bonding metal layer, the reflective layer, the second conductive layer and the active layer, and to the first conductive layer to be connected with the first conductive layer, specifically, the at least one first electrode is insulated from the substrate, the bonding metal layer, the reflective layer, the second conductive layer and the active layer; and
the at least one second electrode is provided on one side of the substrate that is away from the bonding metal layer.

Furthermore, the semiconductor device further includes:
at least one filling slot running from the substrate to the first conductive layer, specifically, the at least one filling slot partially runs into the first conductive layer. The each first electrode is located in one filling slot and connected with the first conductive layer;
an insulating material, the insulating material is provided between a side wall of the filling slot and the first electrode, to insulate the first electrode from the substrate, the bonding metal layer, the reflective layer, the second conductive layer and the active layer.

Furthermore, the semiconductor device further includes at least one groove, with at least one groove is provided on one side of the first conductive layer that is away from the active layer and runs through at least the first conductive layer and the active layer. The at least one groove partitions the semiconductor device into different pixel units.

Furthermore, an insulating layer is provided on a bottom and the side wall of the groove.

Furthermore, the semiconductor device further includes:
a fluorescent powder layer provided on the first conductive layer, the fluorescent powder layer being made from quantum dot fluorescent powder.

Furthermore, the semiconductor device further includes that,
each first electrode extends on the one side of the substrate that is away from the bonding metal layer, to form a connecting pad for connecting with an external drive circuit, and each connecting pad is connected with one first electrode;
each second electrode is located between two adjacent connecting pads and is separated from the two adjacent connecting pads.

The embodiments of the present disclosure further provide a fabrication method for semiconductor device. The method includes steps of:
growing successively, on a base, a first conductive layer, an active layer, a second conductive layer, a reflective layer, a bonding metal layer and a substrate;
forming at least one filling slot on one side of the substrate that is away from the bonding metal layer, specifically, the at least one filling slot running through the substrate, the bonding metal layer, the reflective layer, the second conductive layer, and the active layer, and partially running into the first conductive layer;
fabricating a first electrode in each filling slot in such a way that the first electrode being insulated from the substrate, the bonding metal layer, the reflective layer, the second conductive layer and the active layer;
fabricating at least one second electrode on the one side of the substrate that is away from the bonding metal layer.

Furthermore, fabricating a first electrode in the filling slot includes:
filling the filling slot with an insulating material;
etching the insulating material in the filling slot so as to form an accommodation space for accommodating an electrode material;
filling the accommodation space with the electrode material so as to form the first electrodes, the first electrode being insulated, by remaining insulating material in the filling slot, from the substrate, the bonding metal layer, the reflective layer, the second conductive layer and the active layer.

Furthermore, the step of filling the accommodation space with the electrode material so as to form the first electrode includes:
making the electrode material, which is used for fabricating the first electrode, extend to one side of the substrate that is away from the bonding metal layer, so as to form a connecting pad for connecting with an external drive circuit, and each connecting pad being connected with one first electrode.

Furthermore, the method further includes step of:
removing the base, and forming at least one groove on one side of the first conductive layer that is away from the active layer, with the at least one groove running through at least the first conductive layer and the active layer, the at least one groove partitioning the semiconductor device into different pixel units.

Furthermore, the method further includes steps of:
growing an insulating material on one side of the first conductive layer that is away from the active layer, so as to form an insulating layer grown on the first conductive layer and on a bottom and a side wall of the at least one groove;
etching the insulating material grown on the first conductive layer and forming a fluorescent powder layer on the first conductive layer.

The semiconductor device in the embodiments of the present disclosure is made by the thin-film-flip-chip technology, thus the substrate can be easily removed. Such semiconductor device has features of homogeneous light emission and higher light extraction efficiency. Each pixel unit is separately provided with the first electrode and the second electrode, and the end faces of the first electrode and the second electrode are located on the same side of the device, which is convenient to use the semiconductor device in the future. Each pixel unit is separately provided with the first electrode and the second electrode, which reduces the difference in the equivalent resistance among the pixel units, eliminates the interference among the pixel units, improves homogeneity of the wavelength of the emitted light, and make the distribution of the current flowing through different pixel units more uniform.

To make the above and other purposes, features and advantages of the present disclosure more apparent and understandable, preferred embodiments are provided and detailed with reference to the drawings below.

### BRIEF DESCRIPTION OF DRAWINGS

In order to clearly explain the technical solutions in the embodiments of the present disclosure or in the prior art, figures to be used in the embodiments will be briefly described below. Obviously, the figures in the following description merely show some of the embodiments of the present disclosure. Other figures may be obtained by those ordinarily skilled in the art based on these figures without paying creative efforts. The above and other purposes, features and advantages of the present disclosure will become more apparent from the illustration of the figures. Identical reference signs refer to identical parts throughout the figures. The figures are not intentionally drawn to scale according to the actual dimensions. The point is to illustrate the essence of the present disclosure.

FIG. 1 is an illustrative flow chart of a fabrication method for semiconductor devices provided by embodiments of the present disclosure.

FIGS. 2-14 are structural schematic diagrams of a semiconductor device corresponding to respective processes of the method for the semiconductor devices provided by the embodiments of the present disclosure.

FIG. 15 is a schematic diagram of applying quantum dot fluorescent powder on the semiconductor device provided by the embodiments of the present disclosure.

FIG. 16 is a schematic diagram of a cross-section of the semiconductor device provided by the embodiments of the present disclosure.

FIG. 17 is a schematic diagram of a cross-section of another semiconductor device provided by the embodiments of the present disclosure.

FIG. 18 is a schematic diagram of the semiconductor device, driven in an initiative manner, provided by the embodiments of the present disclosure.

FIG. 19 is a schematic diagram of the semiconductor device, driven in a passive manner, provided by the embodiments of the present disclosure.

### REFERENCE SIGNS

100—base; 101—first conductive layer; 102—active layer; 103—second conductive layer; 104—reflective layer; 105—bonding metal layer; 106—substrate; 107—first electrode; 108—second electrode; 109—groove; 110—insulating material; 111—connecting pad; 112—insulating layer; 113—fluorescent powder layer; 114—cathode; 115—anode; 1071—filling slot; 1131—mask; 1132—quantum dot fluorescent powder.

### DETAILED DESCRIPTION OF EMBODIMENTS

The technical solutions provided in the embodiments of the present disclosure will be clearly and completely described below in combination with the drawings for the embodiments of the present disclosure. Apparently, the embodiments described are merely some but not all of the embodiments of the present disclosure. All the other embodiments obtained by those ordinarily skilled in the art based on the embodiments provided in the present disclosure without paying creative efforts shall fall within the scope of protection of the present disclosure.

It should be noted that similar reference signs and letters refer to similar items in the following figures. Therefore, once an item is defined in a figure, no further definition or explanation for the item is required in the subsequent figures. In addition, in the description of the present disclosure, terms such as “first” and “second” are only used for distinctive purpose, and cannot be construed as indicating or implying relative importance. In the description of the embodiments of the present disclosure, it will be appreciated that, if a layer (or film), region, pattern or structure is referred to be “above” or “below” another substrate, layer (or film), region, pad or pattern, they may be “directly” or “indirectly” located on the another substrate, layer (or film), region, pad or pattern, or one or more intermediate layers may be present therebetween. The positions of such layers are described with reference to the figures. For the purpose of convenience or clarity, the thickness or dimensions of each layer as shown in the figures may be enlarged, omitted or schematically drawn. In addition, the dimensions of elements in the figures do not fully reflect the actual dimensions of the elements.

FIGS. 1-15 show process of a fabrication method for a semiconductor device as described in the preferred embodiments of the present disclosure. Now, the processes will be detailed with reference to the figures. It should be noted that the method described in the embodiments of the present disclosure is not limited to the specific sequence as shown in FIG. 1 or as described below. It should be appreciated that, in other embodiments of the present disclosure, the sequence of partial steps of the method described in the embodiments of the present disclosure may be adjusted interchangeably as required, or part of the steps may be omitted or deleted. As shown in FIG. 1, the fabrication method includes the following steps.

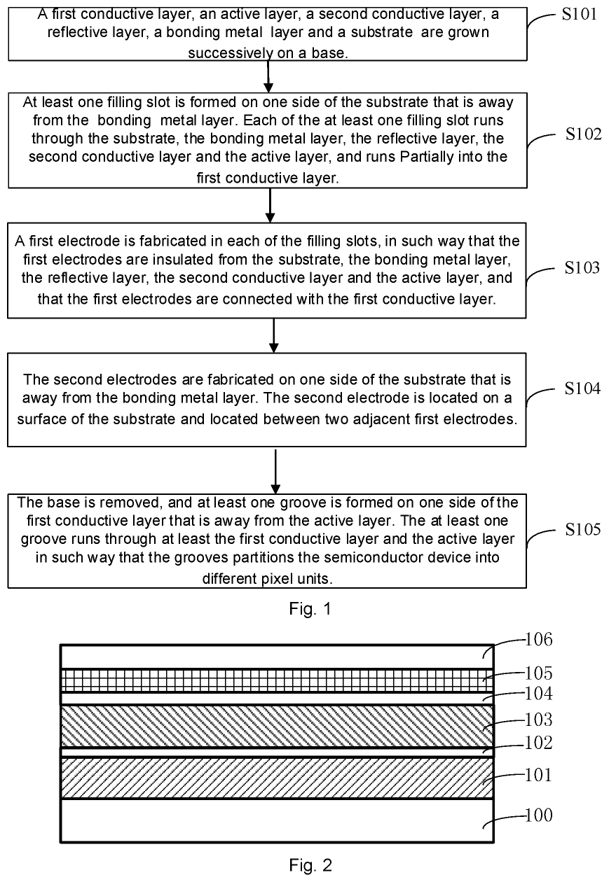

In step S101, a first conductive layer 101, an active layer 102, a second conductive layer 103, a reflective layer 104, a bonding metal layer 105 and a substrate 106 are grown successively on a base 100, as shown in FIG. 2.

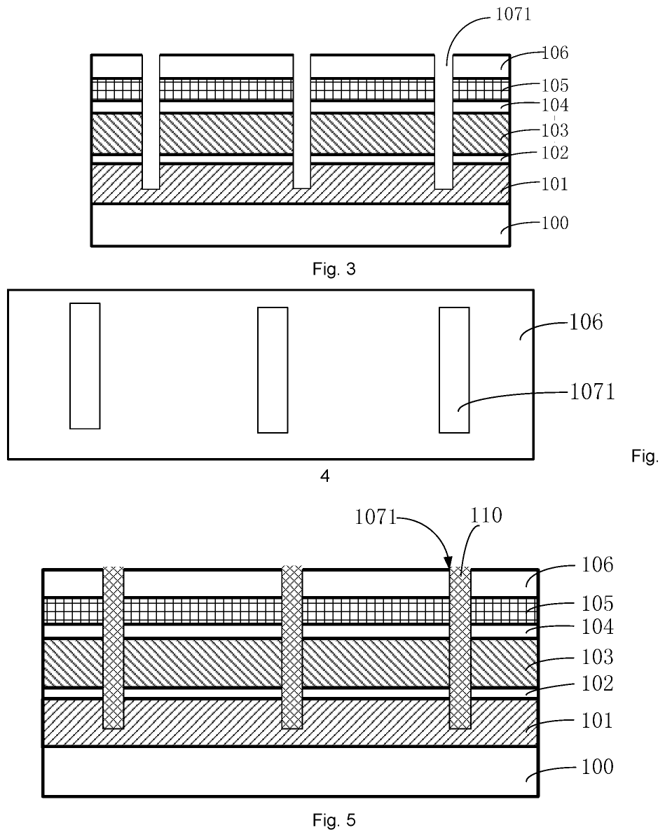

In step S102, at least one filling slot 1071 is formed on one side of the substrate 106 that is away from the bonding metal layer 105, as shown in FIG. 3. Each of the at least one filling slot 1071 runs through the substrate 106, the bonding metal layer 105, the reflective layer 104, the second conductive layer 103 and the active layer 102, and partially runs into the first conductive layer 101.

In the present embodiment, an etching method can be adopted to form the filling slot 1071. The filling slot 1071 successively runs through the substrate 106, the bonding metal layer 105, the reflective layer 104, the second conductive layer 103 and the active layer 102, and extends into first conductive layer 101, rather than running through the first conductive layer 101. In detail, as shown in FIG. 4, the FIG. 4 shows a top view observed from the reflective layer 104 side, with the filling slots 1071 formed. On the plane, the filling slots 1071 may extend for a certain distance.

In step S103, a first electrode 107 is fabricated in each of the filling slots 1071, in such way that the first electrodes 107 are insulated from the substrate 106, the bonding metal layer 105, the reflective layer 104, the second conductive layer 103 and the active layer 102, and that the first electrodes 107 are connected with the first conductive layer 101.

In the present embodiment, the step S103 of forming the first electrodes 107 may specifically include the following substeps.

In substep a, the filling slot 1071 is filled with an insulating material 110, as shown in FIG. 5.

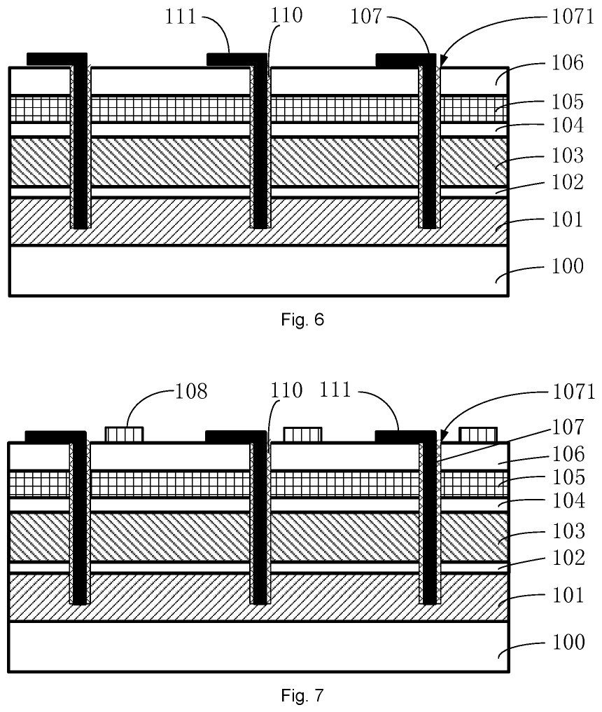

In substep b, the insulating material 110 in the filling slot 1071 is etched, so as to form an accommodation space for accommodating an electrode material. Then, the accommodation space is filled with the electrode material, so as to form the first electrode 107, as shown in FIG. 6.

In the present embodiment, the etching method can be adopted to form the accommodation space, in such way that part of the insulating material 110 remains between the first electrode 107 and sidewalls of the corresponding filling slot 1071, so that the first electrodes 107 are insulated from the substrate 106, the bonding metal layer 105, the reflective layer 104, the second conductive layer 103 and the active layer 102, and that the first electrodes 107 are connected with the first conductive layer 101.

In the present embodiment, the insulating material 110 may be silicon dioxide, silicon nitride or the like, but not limited thereto, and may also be any other suitable insulating materials 110. Specifically, the formation directly on the filling slots 1071 of the insulating material 110 for the purpose of electrical insulation may be realized by chemical vapor deposition, etc., rather than by filling and etching processes or otherwise to realizing the necessary electrical insulation.

Further, in the method, during the formation of the first electrodes 107 in the filling slots 1071, the electrode material for making the first electrodes 107 extends to one side of the substrate 106 that is away from the bonding metal 105, so as to form connecting pads 111 for connecting with an external drive circuit. Each of the connecting pads 111 is connected with one of the first electrodes 107. In other words, the connecting pads 111 may be formed with the first electrodes 107 in a same process.

The electrode materials for making the first electrodes 107 and the connecting pads 111 may consist of one or more material with well conductivity selected from the group including e.g. graphite, copper, silver, zinc, platinum, tantalum nitride, titanium nitride, tantalum, tungsten-based metals or nickel-based metals, but no limitations will be made in this regard in the embodiments of the present disclosure.

In step S104, the second electrodes 108 are fabricated on one side of the substrate 106 that is away from the bonding metal layer 105, as shown in FIG. 7. The second electrode 108 is located on a surface of the substrate 106 and located between two adjacent first electrodes 107.

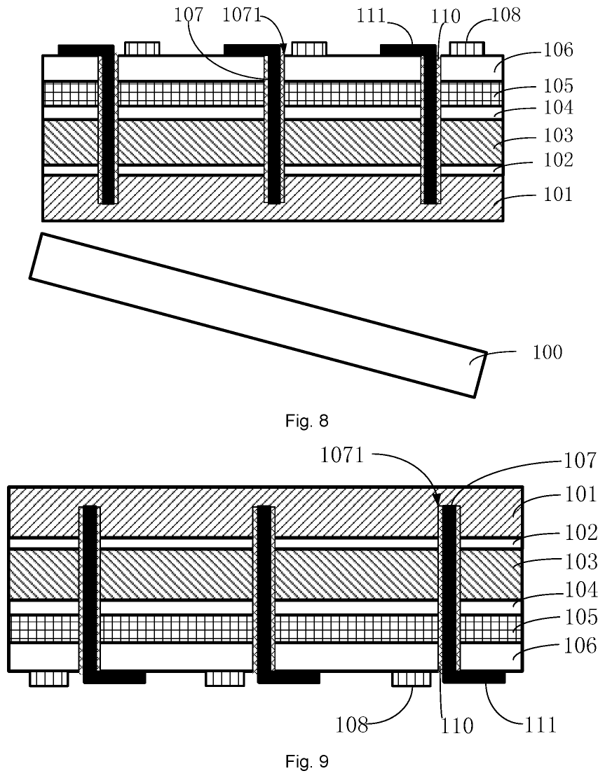

In step S105, the base 100 is removed, and at least one groove is formed on one side of the first conductive layer 101 that is away from the active layer 102. The at least one groove runs through at least the first conductive layer 101 and the active layer 102 in such way that the grooves 109 partition the semiconductor device into different pixel units, as shown in FIGS. 8-10.

The grooves 109 are configured to partition the first conductive layer 101 and the active layer 102 into a plurality of different parts, so as to form a plurality of pixel units. Two adjacent pixel units are separated by one groove 109 and each pixel unit contains a first electrode 107, a second electrode 108 and a connecting pad 111. In a preferred embodiment, the first conductive layer 101 may have N-type conductivity, and the second conductive layer 103 may have P-type conductivity. In the other embodiments of the present disclosure, the grooves 109 may be enabled to partially run into the second conductive layer 103.

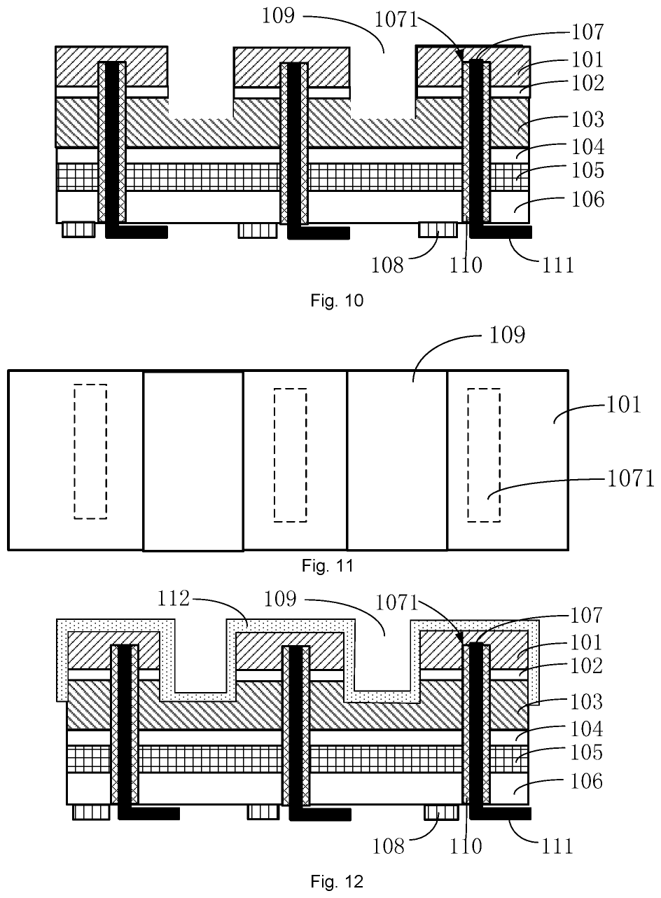

As shown, FIG. 9 is a schematic diagram of the entire structure turned upside down, with the base 100 removed. The grooves 109 are made based on this. It will be appreciated that in a specific structure of the semiconductor device provided by the present embodiment, the grooves 109 preferably run through the first conductive layer 101 and the active layer 102, and may partially run into the second conductive layer 103 rather than running through the second conductive layer 103, as shown in FIG. 10. In the present embodiment, an etching method may be adopted to form the grooves 109.

It will be appreciated that the step of removing the base 100 may be done following the step of forming the grooves 109. Alternatively, the base 100 may be removed after the formations of the first electrodes 107 and the second electrodes 108.

One end of the first electrode 107 is connected with the first conductive layer 101, and the other end extends at one side of the substrate 106 that is away from the bonding metal layer 105, in such way that connecting pads 111 are formed. As the grooves 109 do not run through the second conductive layer 103, a structure may be formed where different pixel units may share the second conductive layer 103. End faces of the first electrodes 107 and the second electrodes 108 are located on the same side of the substrate 106, which is convenient to use the semiconductor device in the future.

In detail, as shown in FIG. 11, FIG. 11 shows a top view observed from the first conductive layer 101 side, with the grooves 109 formed. On the plane, the grooves 109 may extend from one end to the other end of the first conductive layer 101.

Furthermore, the fabrication method may include the following steps.

As shown in FIG. 12, an insulating material 110 is grown on one side of the first conductive layer 101 that is away from the active layer 102, so as to form an insulating layer 112 grown on the first conductive layer 101, at on the bottom and the side wall of the grooves 109.

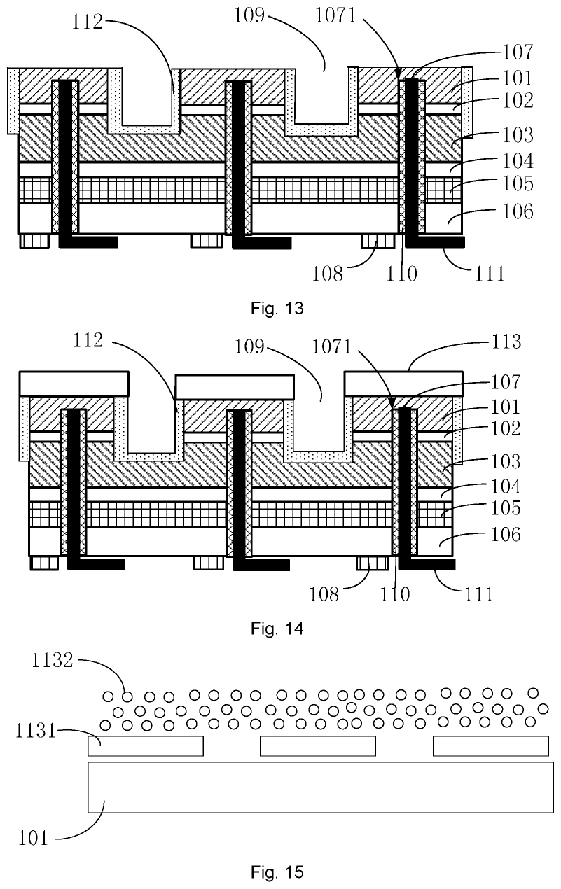

As shown in FIG. 13 and FIG. 14, the insulating layer 112 grown on the first conductive layer 101 is etched, and a fluorescent powder layer 113 is formed on the first conductive layer 101.

It will be appreciated that, in the other embodiments of the present disclosure, the fluorescent powder layers 113 may be directly formed on the first conductive layer 101 after the formation of the grooves 109, without forming the insulating layer 112.

The fluorescent powder layers 113 may be made from fluorescent powder in the form of quantum dot. As shown in FIG. 15, fluorescent powder is deposited in specific areas, by utilizing mask 1131 and utilizing spraying deposition of the solution containing quantum dot fluorescent powder 1132, so as to form the fluorescent powder layers 113. Therefore, the semiconductor device with color display is realized.

A semiconductor device, fabricated by the method provided in the embodiments of the present disclosure, provides homogeneous light emission and higher light extraction efficiency. Moreover, each pixel unit is separately provided with two independent electrodes, which reduces the difference in the equivalent resistance among the pixel units, eliminates the interference among the pixel units, improves homogeneity of the wavelength of the emitted light, and make the distribution of the current flowing through different pixel units more uniform.

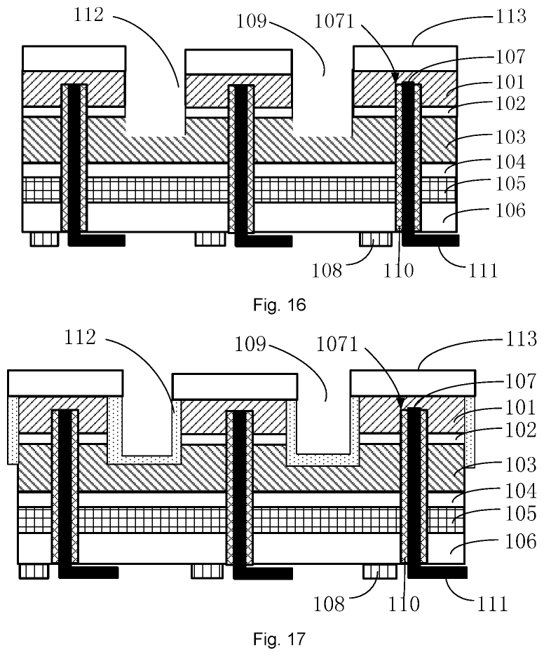

As shown in FIG. 16, a schematic structural diagram of a semiconductor device provided according to an embodiment of the present disclosure is shown. The semiconductor device includes a first conductive layer 101, an active layer 102, a second conductive layer 103, a reflective layer 104, a bonding metal layer 105 and a substrate 106. The bonding metal layer 105 is provided on one side of the substrate 106. The reflective layer 104 is provided on one side of the bonding metal layer 105 that is away from the substrate 106. The second conductive layer 103 is provided on one side of the reflective layer 104 that is away from the bonding metal layer 105. The active layer 102 is provided on one side of the second conductive layer 103 that is away from the reflective layer 104. The first conductive layer 101 is provided on one side of the active layer 102 that is away from the second conductive layer 103.

The semiconductor device further includes at least one first electrode 107 and at least one second electrode 108.

Each of the first electrodes 107 runs from one side of the substrate 106 that is away from the bonding metal layer 105, successively through the substrate 106, the bonding metal layer 105, the reflective layer 104, the second conductive layer 103 and the active layer 102, and extends to the first conductive layer 101. One end of the first electrode 107 is connected with the first conductive layer 101, and the other end extends on one side of the substrate 106 that is away from the bonding metal layer 105, so as to form the connecting pad 111. The first electrode 107 is insulated from the substrate 106, the bonding metal layer 105, the reflective layer 104, the second conductive layer 103 and the active layer 102. In the present embodiment, the semiconductor device is provided with at least one filling slot 1071 which runs from the substrate 106 all the way to the first conductive layer 101. The first electrodes 107 are made of the electrode material for filling the filling slots 1071. Insulating material 110 is provided between a side wall of the filling slot 1071 and the first electrodes 107, to insulate the first electrode 107 from the substrate 106, the bonding metal layer 105, the reflective layer 104, the second conductive layer 103 and the active layer 102.

The second electrodes 108 are provided on one side of the substrate 106 that is away from the bonding metal layer 105. The material of the second electrodes 108 may be the same as the electrode material for forming the first electrodes 107.

In the present embodiment, the first conductive layer 101 may have a P-type conductivity, and the second conductive layer 103 may have a N-type conductivity. Alternatively, the second conductive layer 103 may also be the P-type conductivity, and the first conductive layer 101 may have the N-type conductivity.

Specifically, referring to FIG. 16 again, the semiconductor device provided by the present embodiment further includes at least one groove 109, with each of the at least one groove provided on one side of the first conductive layer 101 that is away from the active layer 102 and running through at least the first conductive layer 101 and the active layer 102. The grooves 109 partition the semiconductor device into a plurality of pixel units. The groove 109 successively runs through the first conductive layer 101 and the active layer 102, but not runs through the second conductive layer 103.

In the embodiments of the present disclosure, each of the pixel units includes one first electrode 107 and one second electrode 108. In each of the pixel units, one end of the first electrode 107 is connected with the first conductive layer 101. As the grooves 109 do not run through the second conductive layer 103, individual parts of the second conductive layer 103 associated with different pixel units are connection with each other, and thus a structure where the different pixel units share the second conductive layer 103 is formed. Preferably, the second conductive layer 103 is provided to have the P-type conductivity and the first conductive layer 101 is provided to have the N-type conductivity, so that a semiconductor device structure with a common P pole is formed. It should be noted that the figure shows only three pixel units for the sake of description. No limitations will be made to the specific number of pixel units in the embodiments of the present disclosure.

Specifically, the substrate 106 is preferably made of silicon, but of course, other materials may also be used. No limitations will be made to the material of the substrate 106 in the embodiments of the present disclosure. In the case that the substrate 106 is made of silicon, the pixel units made on the basis of a silicon wafer may produce light with a better homogeneity. In addition, a silicon wafer substrate is more easily removed than a sapphire substrate.

The reflective layer 104 may reflect part of the light emitted from the active layer 102 and then makes the part of the light go out through the first conductive layer 101. The material of the reflective layer 104 may be silver, aluminum, nickel or one of those metals with light reflecting capability, or metal alloys comprised of a plurality of metals, or a combining metal layer, or may also have a superlattice alloy structure.

The active layer 102 is located between the first conductive layer 101 and the second conductive layer 103, and the active layer 102 may have a quantum well structure. The quantum well structure may include a plurality of quantum well layers and a plurality of quantum barrier layers formed among the quantum well layers. The quantum well layers and the quantum barrier layers may preferably be comprised of AlₓIn_{y}Ga_{1-x-y}N (0<x<1, 0<y<1, 0<x+y<1), in such a way that the energy band of the quantum barrier layers is wider than that of the quantum well layers. As an example, in the case of a gallium nitride based light emitting diode, the first conductive layer 101 may be made of GaN doped with n-type impurities, and the second conductive layer 103 may be made of GaN doped with P-type impurities, and the active layer 102 may be formed by alternatively stacking up the quantum well layers made of AlₓIn_{y}Ga_{1-x-y}N (0<x<1, 0<y<1, 0<x+y<1) and the quantum barrier layers with a wider energy band made of AlInGaN.

Electrons and electron holes injected from the first conductive layer 101 and the second conductive layer 103 are bonded with each other in the active layer 102, so as to emit the light; and the emitted light exits after passing through the first conductive layer 101.

It will be appreciated that the material of the bonding metal layer 105 may be one metal selected from titanium, gold, nickel, tin and platinum, etc., or may be alloys comprised of a plurality of metals, or may be a multi-metal layer.

With the above device structure, a structure where the pixel units share the second conductive layer 103 is formed. The second conductive layer 103 may have the P-type conductivity, and the first conductive layer 101 may have the N-type conductivity. Each pixel unit is provided with a first electrode 107 and a second electrode 108, so that the difference among the equivalent resistance of the pixel units is reduced. Moreover, the problem of inhomogeneous distribution of currents flowing to different pixel units is solved, which problem is otherwise caused by an increased equivalent resistance of a conductive path due to an increased distance from a contacting electrode of an anode 115 for the pixel unit.

It will be appreciated that an insulating layer 112 may also be provided on the bottom and a side wall of each groove 109, as shown in FIG. 17.

Furthermore, in order to provide the semiconductor device with color display, the semiconductor device may further include a fluorescent powder layer 113 provided on the first conductive layer 101, in the embodiments of the present disclosure. The fluorescent powder layer 113 may be made from fluorescent powder in the form of quantum dot.

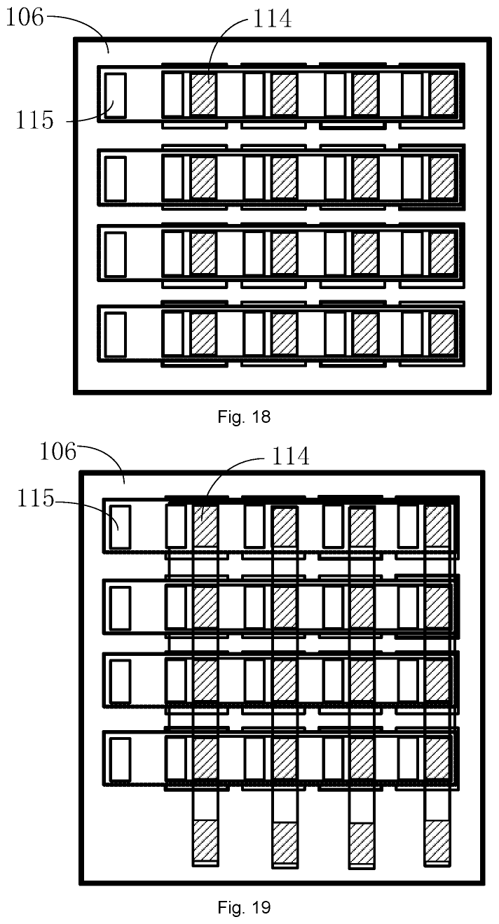

The semiconductor device in the embodiments of the present disclosure needs to be driven by an external drive circuit to emit light. Specifically, as shown in FIG. 18 and FIG. 19, the semiconductor device may be made to be driven in an initiative manner or a passive manner.

It is appreciated that in the case of initiative drive, as shown in FIG. 18, in the structure where the second conductive layer 103 is shared, the first electrode 107 of each pixel unit acts as a cathode 114 and respective electrodes are independent from each other and bond directly with the drive circuit. The first electrodes 107 are connected with the first conductive layer 101, and the first conductive layer 101 may have a n-type conductivity, therefore cathodes 114 to be connected with the negative electrode of the external drive circuit are formed. The second electrodes 108 of the pixel units in each line are connected with the external drive circuit, and individual second electrodes 108 are in electrical conduction with each other.

In the case of passive drive, as shown in FIG. 19, the respective independent second electrodes 108 in the pixel units in each line are connected with each other and then connected with the external drive circuit, forming anodes 115 to be connected with the positive pole of the external drive circuit. The first electrodes 107 of the pixel units in each line are connected with each other and then connected with the external drive circuit, forming cathodes 114 to be connected with the negative pole of the external drive circuit.

In the case of initiative drive, the semiconductor device reacts rapidly and is independent of the number of scanning electrodes, moreover, each pixel unit can perform addressing on their own and be controlled independently. Therefore, such semiconductor device is applicable to many occasions. While, in the case of passive drive, the semiconductor device realizes display in a way of scanning line by line, which has a lower manufacturing cost and a less difficult technology, but fails to provide high resolution display.

To sum up, the semiconductor device provided in the embodiments of the present disclosure provides homogeneous light emission and higher light extraction efficiency. Each pixel unit is separately provided with two independent electrodes, which reduces the difference in the equivalent resistance among the pixel units, eliminates the interference among the pixel units, improves homogeneity of the wavelength of the emitted light, and make the distribution of the current flowing through different pixel units more uniform.

It should also be noted that, in the description of the present disclosure, unless otherwise explicitly specified and defined, terms such as “provide”, “mount”, “couple” and “connect” should be interpreted in a broad sense. For example, a connection may be fixed, detachable, or integrated, or may be mechanical or electrical, or may be direct connection or indirect connection via an intermediate medium, or may be internal communication between two elements. Those ordinarily skilled in the art would understand the specific meanings of the above terms in the present disclosure according to specific circumstances.

It should be noted that similar reference signs and letters refer to similar items in the following figures. Therefore, once an item is defined in a figure, no further definition and explanation for the item is needed in the subsequent figures.

It is to be noted that in the description of the present disclosure, orientation or positional relations indicated by terms such as “center”, “upper”, “lower”, “left”, “right”, “vertical”, “horizontal”, “inner” and “outer” are the orientation or positional relations shown based on the figures, or the conventional orientation or positional relations in the use of the products of the present disclosure, and are only for facilitating and simplifying description of the present disclosure, rather than indicating or implying that the referred devices or elements must be in a particular orientation or constructed or operated in the particular orientation. Therefore, they should not be construed as limiting the present disclosure. In addition, terms such as “first”, “second” and “third” are merely used for distinctive purpose, but should not be construed as indicating or implying relative importance.

The above description only shows the preferable embodiments of the present disclosure and is not intended to limit the present disclosure. Various modifications and variations of the present disclosure will occur to those skilled in the art. Any modifications, equivalent replacements and improvements made within the spirit and principle of the present disclosure shall be encompassed by the scope of protection of the present disclosure.

1. A semiconductor device, comprising a substrate, a bonding metal layer, a reflective layer, a first conductive layer, an active layer, a second conductive layer, at least one first electrode and at least one second electrode,
wherein the bonding metal layer is provided on one side of the substrate;
the reflective layer is provided on one side of the bonding metal layer that is away from the substrate;
the second conductive layer is provided on one side of the reflective layer that is away from the bonding metal layer;
the active layer is provided on one side of the second conductive layer that is away from the reflective layer;
the first conductive layer is provided on one side of the active layer that is away from the second conductive layer;
the at least one first electrode runs, from one side of the substrate that is away from the bonding metal layer, successively through the substrate, the bonding metal layer, the reflective layer, the second conductive layer and the active layer, and to the first conductive layer to be connected with the first conductive layer, wherein the at least one first electrode is insulated from the substrate, the bonding metal layer, the reflective layer, the second conductive layer and the active layer; and
the at least one second electrode is provided on the one side of the substrate that is away from the bonding metal layer.

2. The semiconductor device according to claim 1, wherein the semiconductor device further comprises:
at least one filling slot running from the substrate to the first conductive layer, wherein the at least one filling slot runs through the substrate, the bonding metal layer, the reflective layer, the second conductive layer and the active layer, and partially runs into the first conductive layer, and the each first electrode is located in one filling slot and connected with the first conductive layer;
wherein an insulating material is provided between the first electrode and a side wall of the filling slot, to insulate the first electrode from the substrate, the bonding metal layer, the reflective layer, the second conductive layer and the active layer.

3. The semiconductor device according to claim 1, wherein the semiconductor device further comprises at least one groove, with at least one groove is provided on one side of the first conductive layer that is away from the active layer and runs through at least the first conductive layer and the active layer, and the at least one groove partitions the semiconductor device into different pixel units.

4. The semiconductor device according to claim 3, wherein an insulating layer is provided on a bottom and the side wall of the groove.

5. The semiconductor device according to claim 1, wherein the semiconductor device further comprises:
a fluorescent powder layer provided on the first conductive layer, the fluorescent powder layer being made from quantum dot fluorescent powder.

6. The semiconductor device according to claim 1, wherein each first electrode extends on the one side of the substrate that is away from the bonding metal layer, to form a connecting pad for connection with an external drive circuit, and each connecting pad is connected with one first electrode; and
each second electrode is located between two adjacent connecting pads, and is separated from the two adjacent connecting pads.

7. A fabrication method for a semiconductor device, comprising steps of:
growing successively, on a base, a first conductive layer, an active layer, a second conductive layer, a reflective layer, a bonding metal layer and a substrate;
forming at least one filling slot on one side of the substrate that is away from the bonding metal layer, wherein the at least one filling slot runs through the substrate, the bonding metal layer, the reflective layer, the second conductive layer and the active layer, and partially runs into the first conductive layer;
fabricating a first electrode in each filling slot in such a way that the first electrode is insulated from the substrate, the bonding metal layer, the reflective layer, the second conductive layer and the active layer, and that the first electrode is connected with the first conductive layer; and
fabricating at least one second electrode on the one side of the substrate that is away from the bonding metal layer.

8. The fabrication method according to claim 7, wherein the step of fabricating a first electrode in each filling slot comprises steps of:
filling the filling slot with an insulating material;
etching the insulating material in the filling slot, so as to form an accommodation space for accommodating an electrode material; and
filling the accommodation space with the electrode material so as to form the first electrode, wherein the first electrode is insulated, by remaining insulating material in the filling slot, from the substrate, the bonding metal layer, the reflective layer, the second conductive layer and the active layer.

9. The fabrication method according to claim 8, wherein the step of filling the accommodation space with the electrode material so as to form the first electrode comprises:
making the electrode material, which is used for fabricating the first electrode, extend to one side of the substrate that is away from the bonding metal layer, so as to form a connecting pad for connection with an external drive circuit, wherein each connecting pad is connected with one first electrode.

10. The fabrication method according to claim 7, wherein the fabrication method further comprises:
removing the base, and forming at least one groove on one side of the first conductive layer that is away from the active layer, with the at least one groove running through at least the first conductive layer and the active layer, wherein the at least one groove partitions the semiconductor device into different pixel units.

11. The fabrication method according to claim 10, wherein the method further comprises:
growing an insulating material on one side of the first conductive layer that is away from the active layer, so as to form an insulating layer grown on the first conductive layer and on a bottom and the side wall of the at least one groove; and
etching the insulating material grown on the first conductive layer, and forming a fluorescent powder layer on the first conductive layer.

12. The semiconductor device according to claim 2, wherein the semiconductor device further comprises at least one groove, with at least one groove is provided on one side of the first conductive layer that is away from the active layer and runs through at least the first conductive layer and the active layer, and the at least one groove partitions the semiconductor device into different pixel units.

13. The semiconductor device according to claim 2, wherein the semiconductor device further comprises:
a fluorescent powder layer provided on the first conductive layer, the fluorescent powder layer being made from quantum dot fluorescent powder.
